(19) United States
(12) Patent Application Publication
(10) Pub. No.: US 2011/0094781 A1
(43) Pub. Date: Apr. 28, 2011

(54) ELECTRONIC DEVICE HAVING A GLASS SUBSTRATE CONTAINING SODIUM AND METHOD OF MANUFACTURING THE SAME

(76) Inventors: Tadahiro Ohmi, Miyagi (JP); Kohei Watanuki, Tokyo (JP); Hirokazu Suzuki, Tokyo (JP)

(21) Appl. No.: 13/001,807

(22) PCT Filed: Jun. 25, 2009
(86) PCT No.: PCT/JP2009/061562

§ 371 Date: Dec. 29, 2010

(30) Foreign Application Priority Data
Jun. 30, 2008 (JP) 2008-171493

(51) Int. Cl. H05K 1/03; B05D 5/12

(52) U.S. Cl. 174/258; 427/58

(57) ABSTRACT

An electronic device comprises a glass substrate (10) containing sodium, and a sodium diffusion-preventing film (11) which is a planarization coating film formed on the glass substrate (10). An electronic element (12) is formed on the sodium diffusion-preventing film (11).

### TECHNICAL FIELD

This invention relates to an electronic device such as a solar cell or a large-size display having a glass substrate containing sodium and to a method of manufacturing the same and, in particular, relates to an electronic device having an electronic element which is formed over a glass substrate containing sodium through a sodium diffusion preventing layer and to a method of manufacturing the same.

### BACKGROUND ART

A glass substrate is used in an electronic device such as a solar cell or a large-size flat panel display. Since an inexpensive glass substrate such as a soda-lime glass substrate contains sodium, if electronic elements such as solar cell elements, display elements, or switching elements are formed on this type of glass substrate, sodium in the glass substrate diffuses into the electronic elements to degrade the characteristics of the electronic elements. Therefore, a glass containing sodium cannot be used for forming a long-life high-performance electronic device and thus an expensive non-alkali glass free of sodium has normally been used.

However, with the increase in area and cost of glass substrates following the increase in size of electronic devices, it has been strongly desired to employ inexpensive glass substrates for reducing the cost of large-size electronic devices.

In order to use an inexpensive glass substrate containing sodium, it is known to form a sodium diffusion preventing layer on the glass substrate (Patent Document 1, Patent Document 2).

PRIOR ART DOCUMENT

Patent Document

Patent Document 1: JP-A-2000-243327

Patent Document 2: JP-A-2000-26139

### SUMMARY OF THE INVENTION

### Problem to be Solved by the Invention

Patent Document 1 discloses that one of a silica film, a silica film doped with phosphorus, a silicon oxynitride film, a silicon nitride film, and so on is formed to a thickness of 500 nm by sputtering or the like as a sodium diffusion preventing layer, which, however, is costly when applied to a large-size glass substrate and further cannot achieve a high sodium diffusion preventing effect.

It is therefore an object of this invention to provide an electronic device that can be easily and inexpensively applied to a large-size glass substrate, and a method of manufacturing such an electronic device.

It is another object of this invention to provide an electronic device having a sodium diffusion preventing layer with a high sodium diffusion preventing effect and a method of manufacturing such an electronic device.

### MEANS FOR SOLVING THE PROBLEM

According to this invention, there is obtained an electronic device. The electronic device comprises a glass substrate containing sodium and a sodium diffusion preventing layer in the form of a planarization coating film provided on the glass substrate. An electronic element is formed on the sodium diffusion preventing layer.

The sodium diffusion preventing layer preferably comprises a coating film expressed by a general formula of ((CH₃)SiO_{3/2})ₓ(SiO₂)₁₋ₓ (where 0<x≦1.0). It is preferable particularly in terms of the sodium diffusion preventing effect that the permittivity of the sodium diffusion preventing layer be 3.0 or less.

The thickness of the sodium diffusion preventing layer can be as thin as 150 to 300 nm. The sodium diffusion preventing layer is preferably transparent.

According to this invention, there is obtained an electronic device manufacturing method characterized by comprising a step of coating a coating film having a composition expressed by a general formula of ((CH₃)SiO_{3/2})ₓ(SiO₂)₁₋ₓ (where 0<x≦1.0) on at least one of main surfaces of a glass substrate containing sodium and a step of heat-treating the coating film at a temperature of 400° C. or less. Specifically, this manufacturing method comprises a step of coating, on at least one of main surfaces of a glass substrate containing sodium, a coating liquid containing a condensate obtained by a hydrolysis-condensation reaction of a mixture of a methyltrialkoxysilane compound and a tetraalkoxysilane compound, thereby forming a coating film, and a step of heat-treating the coating film at a temperature of 400° C. or less.

x is preferably 0.6≦x≦0.9 and more preferably 0.7≦x≦0.9.

### EFFECT OF THE INVENTION

According to this invention, it is possible to provide an electronic device that can be easily and inexpensively applied to a large-size glass substrate and has a sodium diffusion preventing layer with a high sodium diffusion preventing effect, and a method of manufacturing such an electronic device.

### BRIEF DESCRIPTION OF THE DRAWINGS

FIG. 1 is a diagram for explaining Example 1 of this invention and is a diagram for explaining the IR absorbance of coating-type sodium diffusion preventing films.

FIG. 2 is a diagram for explaining Example 1 of this invention and is a correlation diagram of the peak intensity ratios of Si—CH₃ to Si—O—Si of the IR absorbance shown in FIG. 1 and the permittivities of the films.

FIG. 3 is a diagram for explaining the electrical properties of an insulating coating film according to this invention.

FIG. 4 is a diagram for explaining Example 1 of this invention and is a diagram explaining the SIMS analysis results of the permittivity and the sodium diffusion preventing performance of the coating-type sodium diffusion preventing film immediately after carrying out baking for 2 hours at 400° C. at a reduced pressure of 5 Torr after coating a film AF-0,being one kind of the sodium diffusion preventing films, on a glass substrate containing sodium, and after carrying out, thereafter, a nitrogen anneal for 1 hour at 500° C. under normal pressure.

FIG. 5 is a diagram for explaining Example 1 of this invention and a Comparative Example and is a diagram explaining the SIMS analysis results of the permittivity and the sodium diffusion preventing performance of the coating-type sodium diffusion preventing film immediately after carrying out baking for 2 hours at 400° C. at a reduced pressure of 5 Torr after coating a film AF-4, being one kind of the sodium diffusion preventing films, on a glass substrate containing sodium, and after carrying out, thereafter, a nitrogen anneal for 1 hour at 500° C. under normal pressure for confirming the sodium diffusion preventing performance.

FIG. 6 is a diagram for explaining Example 1 of this invention and a Comparative Example and is a diagram explaining the SIMS analysis results of the permittivity and the sodium diffusion preventing performance of the coating-type sodium diffusion preventing film immediately after carrying out baking for 2 hours at 400° C. at a reduced pressure of 5 Torr after coating a film AF-6GM, being one kind of the sodium diffusion preventing films, on a glass substrate containing sodium, and after carrying out, thereafter, a nitrogen anneal for 1 hour at 500° C. under normal pressure for confirming the sodium diffusion preventing performance.

FIG. 7 is a diagram for explaining Example 1 of this invention and a Comparative Example and is a diagram explaining the permittivity and the sodium diffusion preventing performance of the coating-type sodium diffusion preventing films immediately after carrying out baking for 2 hours at 400° C. at a reduced pressure of 5 Torr after coating each of the sodium diffusion preventing films on a glass substrate containing sodium.

FIG. 8 is a diagram for explaining Example 1 of this invention and a Comparative Example and is a diagram explaining the permittivity and the sodium diffusion preventing performance of the coating-type sodium diffusion preventing films after carrying out a nitrogen anneal for 1 hour at 500° C. under normal pressure for confirming the sodium diffusion preventing performance immediately after carrying out baking for 2 hours at 400° C. at a reduced pressure of 5 Torr after coating each of the sodium diffusion preventing films on a glass substrate containing sodium.

FIG. 9 is a diagram showing one example of an electronic device to which this invention is applied.

### MODE FOR CARRYING OUT THE INVENTION

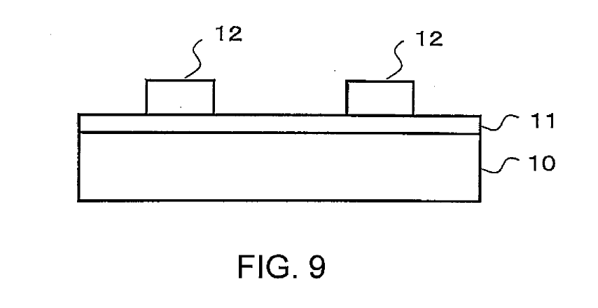

FIG. 9 shows one example of an electronic device to which this invention is applied. In FIG. 9, electronic elements 12 such as solar cell elements or display elements are formed over a glass substrate 10 containing sodium through a sodium diffusion preventing film 11.

The formation of the sodium diffusion preventing film and a coating liquid therefor film will be described hereinbelow.

1. Kind of Solvent of Coating Liquid:

Use can be made of organic solvents such as, alcohols such as methanol, ethanol, isopropyl alcohol, propyl alcohol, and cyclohexanol, glycols such as ethylene glycol and propylene glycol and derivatives thereof, ketones such as acetone, methyl isobutyl ketone, and cyclohexanone, toluenes, xylenes, ethers, and aliphatic hydrocarbons, water, and so on. These may be used alone or as a mixture of two or more kinds.

2. Kind of Coating Liquid:

A coating liquid is one kind selected from mixed liquids in which a condensate (condensate C) obtained by a hydrolysis-condensation reaction of a mixture of

a methyltrialkoxysilane compound (silane compound A) such as methyltrimethoxysilane, methyltriethoxysilane, methyltripropoxysilane, or methyltriisopropoxysilane; and

a tetraalkoxysilane compound (silane compound B) such as tetramethoxysilane, tetraethoxysilane, tetra-n-propoxysilane, tetraisopropoxysilane, tetra-n-butoxysilane, tetraisobutoxysilane, tetra-sec-butoxysilane, or tetra-tert-butoxysilane is dissolved or dispersed in the above-mentioned solvents, respectively, or is obtained by mixing two or more kinds of the mixed liquids.

Using mixtures of a silane compound A and a silane compound B with different molar ratios, it is possible to obtain various condensates C with different molar ratios after hydrolysis-condensation reactions, respectively.

A condensate C can be synthesized by a hydrolysis-condensation reaction of a mixture of a silane compound A and a silane compound B, wherein, for example, by the use of a reactor with an agitator, agitation is carried out for about 1 to 24 hours at a temperature of 0 to 80° C. in a predetermined solvent using an acid or a base as a catalyst with the addition of water.

The content of the condensate C in the coating liquid is not particularly limited, but is normally 0.1 to 25 wt %. Although the optimal value differs depending on a coating method and the setting of film thickness, it is preferably 0.2 to 10 wt % in terms of temporal changes of the coating agent.

3. Other Component:

The coating liquid may be added with a leveling agent, a viscosity modifier, or the like.

The sodium diffusion preventing film should be formed as a dense film with less or no defects such as voids in the film and can be formed by processes including

1) a solvent removal process of coating a coating liquid on a glass substrate containing sodium and then carrying out heating, preferably at a reduced pressure, to remove volatile matter such as a solvent,

2) then, a film forming process of carrying out heating in the range of 300 to 500° C., preferably 320 to 480° C., more preferably 350 to 450° C., and particularly preferably 380 to 420° C. at a reduced pressure of 100 Torr or less (100×133.3 Pa or less), preferably 0.1 to 50 Torr (13.3 to 6665 Pa), and more preferably 0.5 to 10 Torr (66.6 to 1333 Pa), and

3) if necessary, a subsequent heating process of performing heating at a temperature and in an atmosphere where the glass substrate containing sodium and a condensate expressed by a general formula of ((CH₃)SiO_{3/2})ₓ(SiO₂)₁₋ₓ (where 0<x≦1.0)do not impair the object of this invention (e.g. 500° C., nitrogen atmosphere, etc.).

In the film forming process,

i) it is necessary to further carry out film formation on the sodium diffusion preventing film by a vacuum treatment such as plasma CVD or sputtering depending on a purpose and thus to completely remove released gas components,

ii) the condensate expressed by the general formula of ((CH₃)SiO_{3/2})ₓ(SiO₂)₁₋ₓ (where 0<x≦1.0)can be obtained from the condensate C by dehydration condensation or the like,

iii) the preferable range of the upper and lower limits is described as the reduced pressure condition for the film formation in terms of industrial aspect, but it is preferable that, for this purpose, the reduced pressure condition be arbitrarily set other than the above, and

iv) in terms of the decomposition temperature of the condensate C, the glass substrate, and the permittivity after the formation, the heating temperature is preferably in the above-mentioned range.

### Example

(Manufacture of Coating Liquid)

1 part of methyltrimethoxysilane, 0.47 parts of tetraethoxysilane, 3.1 parts of isopropyl alcohol, 1 part of 0.1 N nitric acid, and 8.8 parts of water were mixed in order, thereby carrying out a hydrolysis-condensation reaction for 24 hours. An obtained reaction liquid was diluted with a mixed solvent of 8.4 parts of methyl isobutyl ketone and 5.3 parts of propylene glycol monomethyl ether, thereby obtaining a coating liquid. By changing the mixing ratio of methyltrimethoxysilane and tetraethoxysilane, various coating liquids can be manufactured.

### Example 1

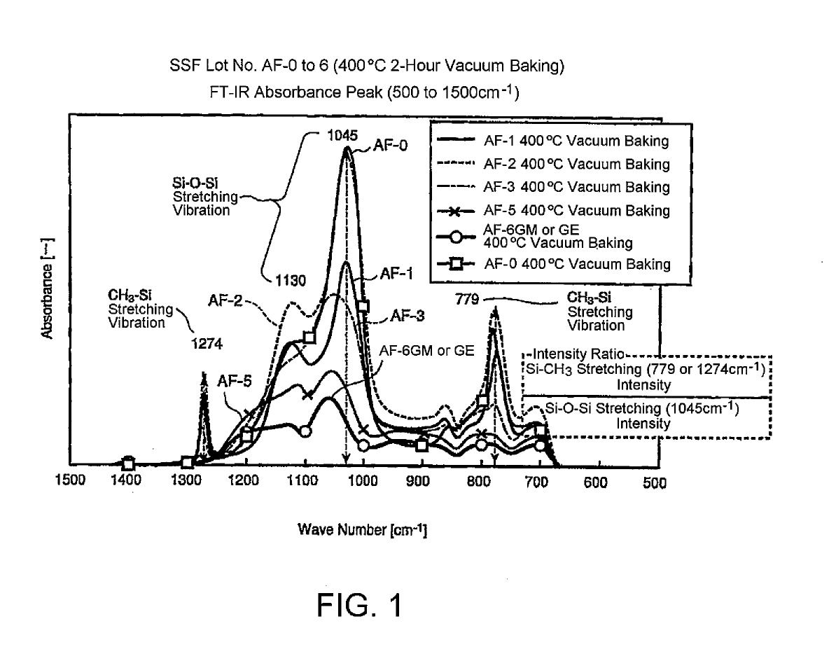

FIG. 1 is a diagram showing the IR (Infrared) absorbance of coating-type sodium diffusion preventing films (or layers). Specifically, the IR absorbance of Si—CH₃ is observed at wave numbers of 779 cm⁻¹ and 1274 cm⁻¹ and the IR absorbance of Si—O—Si is observed at wave numbers of 1045 to 1130 cm⁻¹ . Therefore, the various coating-type sodium diffusion preventing films (lot numbers AF-0, AF-1, AF-2, AF-3, AF-5, and AF-6GM or GE) are respectively formed of materials each having a composition of ((CH₃)SiO_{3/2})ₓ(SiO₂)₁₋ₓ (where 0<x≦1.0), preferably 0.7≦x≦0.9).

x in the respective lot numbers is as follows, wherein AF-6GM and AF-6GE are shown as a Comparative Example.

AF-0: x=0.7

AF-1: x=1.0

AF-2: x=0.9

AF-3: x=0.5

AF-4: x=0.3

AF-5: x=0.1

AF-6GM: x=0

AF-6GE: x=0

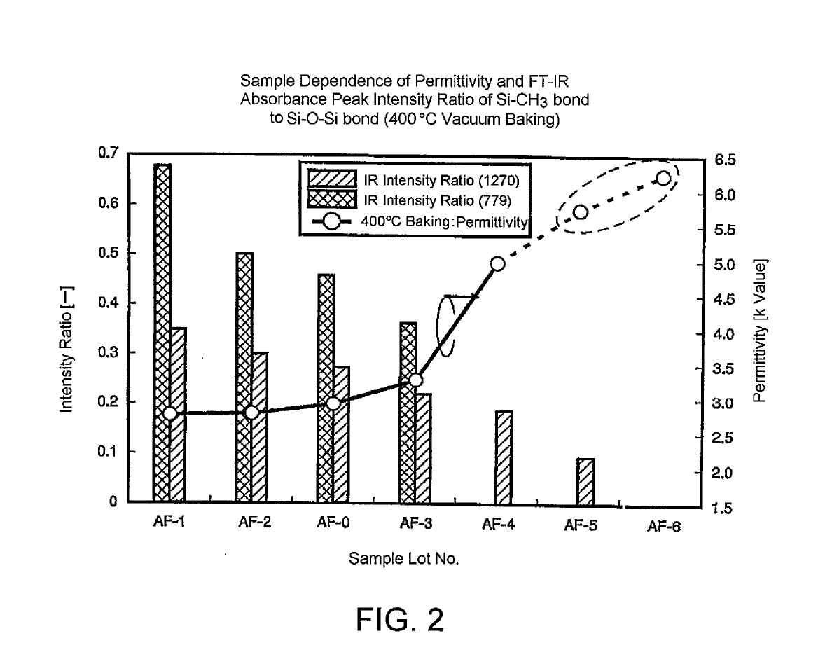

FIG. 2 shows the peak intensity ratios of Si—CH₃ to Si—O—Si of the IR absorbance shown in FIG. 1 and the permittivities of the films. As is also clear from the composition of ((CH₃)SiO_{3/2})ₓ(SiO₂)₁₋ₓ, the permittivity decreases as the intensity ratio of Si—CH₃ increases, while, as it decreases, the composition approaches SiO₂ and its permittivity increases.

On the other hand, in a baking process, after coating an organic solvent solution of the material of the above-mentioned composition, i.e. the composition of ((CH₃)SiO_{3/2})ₓ(SiO₂)₁₋ₓ, on a soda-lime glass surface, heating is carried out at a reduced pressure to completely remove the solvent. Heating is carried out at 400° C. at a reduced pressure of 1 to 5 Torr (133 to 665 Pa).

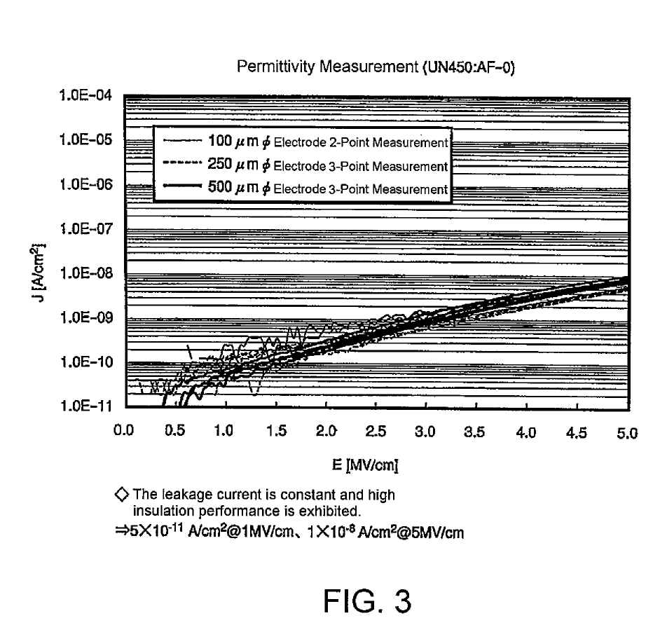

As shown in FIG. 3, the insulating properties of a film thus formed show excellent values such as a current density of 1×10⁻¹⁰ A/cm² at 1 MV/cm, a current density of 1×10⁻⁹ A/cm² at 3 MV/cm, and a current density of 1×10⁻⁸ A/cm² even at 5 MV/cm.

Next, the results of the sodium diffusion preventing performance of the above-mentioned coating-type sodium diffusion preventing films will be shown.

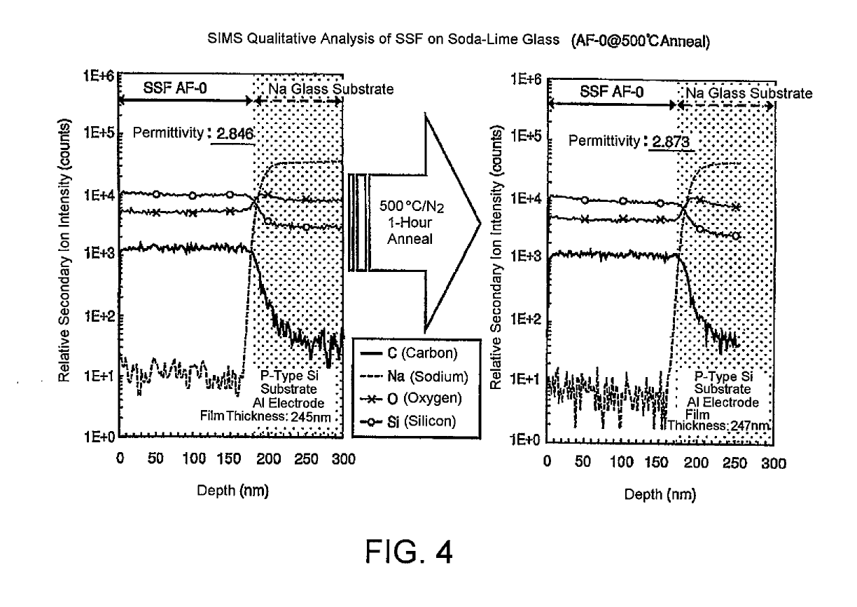

FIG. 4 shows the SIMS (Secondary Ionization Mass Spectrometer) analysis results of the permittivity and the sodium diffusion preventing performance of the coating-type sodium diffusion preventing film immediately after carrying out baking for 2 hours at 400° C. at a reduced pressure of 5 Torr (665 Pa) after coating the film AF-0 on a glass substrate containing sodium, and after carrying out, thereafter, a nitrogen anneal for 1 hour at 500° C. under normal pressure for confirming the sodium diffusion preventing performance. Herein, the coating-type sodium diffusion preventing film is a transparent planarization coating film having a thickness of 247 nm. The thickness is preferably in the range of 150 to 300 nm. The analysis results show that there was almost no difference in sodium diffusion into the film AF-0 from the glass substrate containing sodium between that after the baking and that after the anneal and thus the sodium diffusion was prevented. That is, although 400° C. is required for baking the coating film, there is no thermal diffusion of sodium at 400° C. in the baking and, further, even if the heat treatment (1-hour anneal) is carried out at the higher temperature (500° C.), no sodium diffusion is observed.

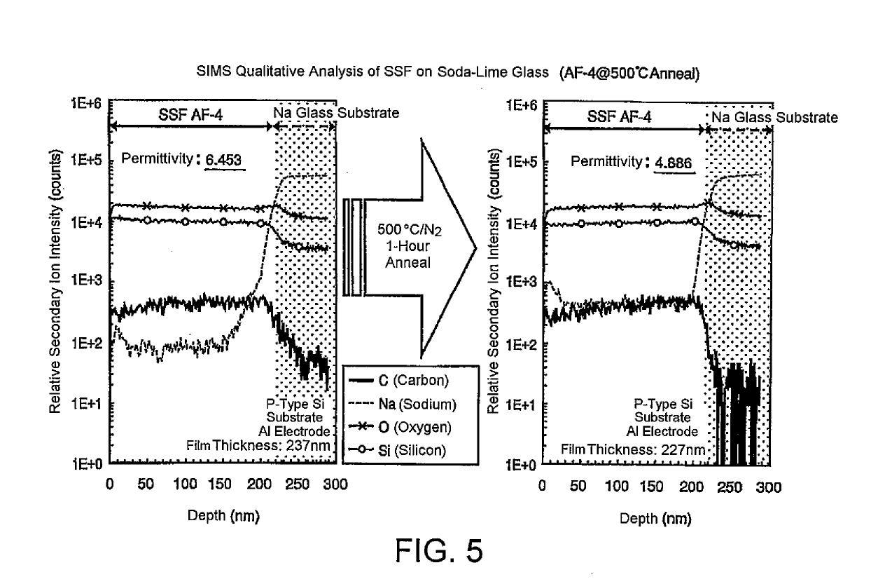

FIG. 5 shows the SIMS analysis results of the permittivity and the sodium diffusion preventing performance of the coating-type sodium diffusion preventing film (thickness 227 nm) immediately after carrying out baking for 2 hours at 400° C. at a reduced pressure of 5 Torr (665 Pa) after coating the film AF-4 (x=0.3), in place of the film AF-0, on a glass substrate containing sodium, and after carrying out, thereafter, a nitrogen anneal for 1 hour at 500° C. under normal pressure for confirming the sodium diffusion preventing performance. From the analysis results, it is confirmed that sodium slightly diffused into the film AF-4 and it is seen that the permittivity of the film also increased slightly.

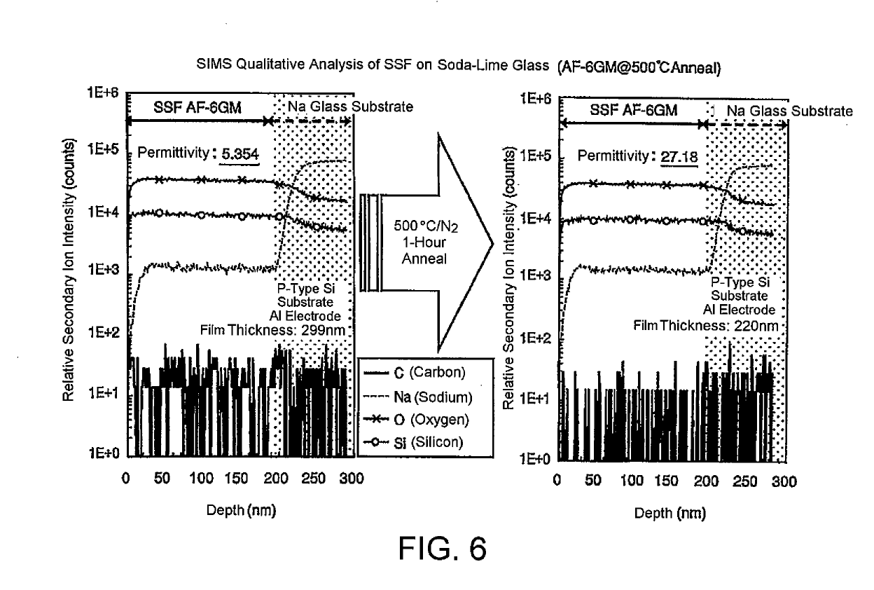

Finally, FIG. 6 shows the SIMS analysis results of the permittivity and the sodium diffusion preventing performance of the coating-type sodium diffusion preventing film (thickness 220 nm) immediately after carrying out baking for 2 hours at 400° C. at a reduced pressure of 5 Torr (665 Pa) after coating the film AF-6GM on a glass substrate containing sodium, and after carrying out, thereafter, a nitrogen anneal for 1 hour at 500° C. under normal pressure for confirming the sodium diffusion preventing performance. From the analysis results, it is confirmed that sodium completely diffused into the film AF-6GM and it is seen that the permittivity of the film also increased largely.

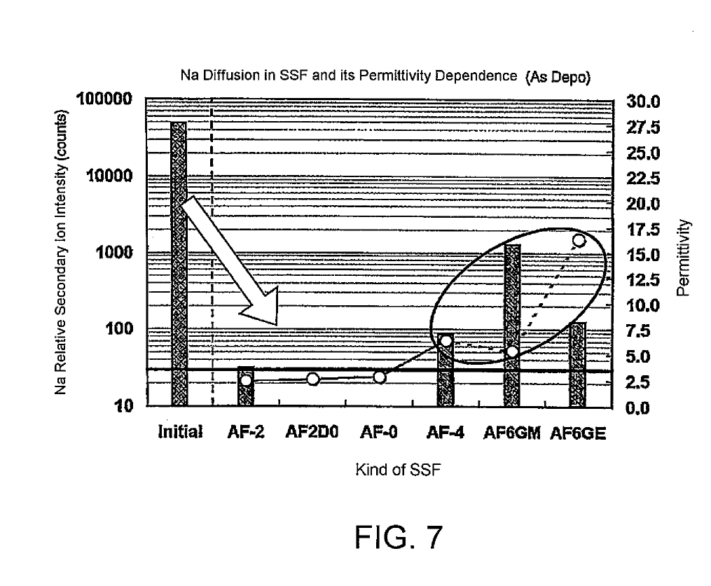

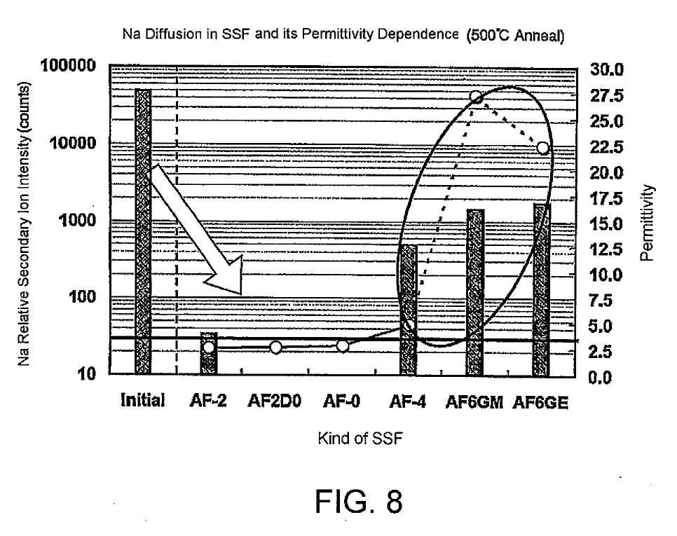

FIGS. 7 and 8 show the above-mentioned results and the results of the permittivity/sodium diffusion ratios of the other kinds of coating-type sodium diffusion preventing films.

FIG. 7 shows the sodium diffusion intensities (sodium relative secondary ion intensities) into the various coating-type sodium diffusion preventing films after baking for 2 hours at 400° C. at a reduced pressure of 5 Torr (665 Pa) and the permittivities of the films.

FIG. 8 shows the sodium diffusion intensities into the various coating-type sodium diffusion preventing films after carrying out a nitrogen anneal for 1 hour at 500° C. under normal pressure for confirming the sodium diffusion preventing performance after baking for 2 hours at 400° C. at a reduced pressure of 5 Torr (665 Pa) and the permittivities of the films.

From FIGS. 7 and 8, it is seen that if the permittivity of the coating-type sodium diffusion preventing film is 3.0 or less, it is possible to prevent thermal diffusion of sodium into the film from the glass substrate containing sodium.

While the Example of this invention has been described, when this invention is applied to an electronic device, electronic elements are formed on the above-mentioned sodium diffusion preventing film. The electronic elements include, for example, solar cell elements, display elements, or the like.

### DESCRIPTION OF SYMBOLS

10 glass substrate

11 sodium diffusion preventing film

12 electronic element

1. An electronic device characterized by comprising a glass substrate containing sodium and a sodium diffusion preventing layer in the form of a planarization coating film provided on the glass substrate, wherein an electronic element is formed on the sodium diffusion preventing layer.

2. The electronic device according to claim 1, characterized in that the sodium diffusion preventing layer contains a composition expressed by a general formula of ((CH₃)SiO_{3/2})ₓ(SiO₂)₁₋ₓ (where 0<x≦1.0).

3. The electronic device according to claim 2, characterized in that a value of x in the general formula is 0.6≦x≦0.9.

4. The electronic device according to claim 1, characterized in that the sodium diffusion preventing layer has a permittivity of 3.0 or less.

5. The electronic device according to claim 1, 2, or 4, characterized in that the sodium diffusion preventing layer has a thickness of 150 to 300 nm.

6. The electronic device according to claim 2, characterized in that the sodium diffusion preventing layer is transparent.

7. The electronic device according to claim 6, characterized in that the electronic element is a solar cell element.

8. The electronic device according to claim 6, characterized in that the electronic element comprises a display element.

9. An electronic device manufacturing method characterized by comprising a step of coating, on at least one of main surfaces of a glass substrate containing sodium, a coating liquid containing a condensate obtained by a hydrolysis-condensation reaction of a mixture of a methyltrialkoxysilane compound and a tetraalkoxysilane compound, thereby forming a coating film, and a step of heat-treating the coating film at a temperature of 400° C. or less.
